(19) United States
(12) Patent Application Publication
(10) Pub. No.: US 2025/0338677 A1
(43) Pub. Date: Oct. 30, 2025

(54) SEMICONDUCTOR DEVICE

(71) Applicant: EPISTAR CORPORATION, Hsinchu (TW)

(72) Inventors: Zhen-Kai KAO, Hsinchu (TW); Chih-Ming WANG, Hsinchu (TW); Hui-Ching FENG, Hsinchu (TW); Yih-Hua RENN, Hsinchu (TW); Min-Hsun HSIEH, Hsinchu (TW)

(21) Appl. No.: 19/195,348

(22) Filed: Apr. 30, 2025

(30) Foreign Application Priority Data
Apr. 30, 2024 (TW) 113116226

(51) Int. Cl. H10H 20/84; H10H 20/01; H10H 20/82; H10H 20/831; H10H 20/833; H10H 20/857

(52) U.S. Cl. CPC H10H 20/84; H10H 20/019; H10H 20/034; H10H 20/0364; H10H 20/82; H10H 20/831; H10H 20/833; H10H 20/857

(57) ABSTRACT

A semiconductor device is provided, which includes an epitaxial structure, a first electrode, an insulating structure, a stop layer, and a second electrode. The epitaxial structure includes a first semiconductor layer, a second semiconductor layer and an active region located between the first semiconductor layer and the second semiconductor layer. The second semiconductor layer has a first portion and a second portion. The first portion has a first side surface. The first electrode is located under the first semiconductor layer. The insulating structure distributed on the first side surface and having an opening which corresponds to the first electrode. The stop layer contacts the insulating structure distributed on the first side surface. The second electrode is located on the second semiconductor layer. The first portion has a first width, and the second portion has a second width less than the first width.

### CROSS REFERENCE TO RELATED APPLICATIONS

This application claims the right of priority based on TW application No. 113116226, filed on Apr. 30, 2024, which is incorporated by reference herein in its entirety.

### FIELD OF DISCLOSURE

The present disclosure relates to a semiconductor device, and, in particular, to a semiconductor optoelectronic device.

### BACKGROUND OF THE DISCLOSURE

Semiconductor devices are widely used in illumination, medical, display, communication, sensing, power supply systems and other fields, and the development and research of related materials and products is also ongoing. Group III-V semiconductor materials including Group III and Group V elements may be applied to various semiconductor optoelectronic devices, for example, in light-emitting devices such as light-emitting diodes (LEDs), laser diodes (LDs), light-absorbing devices such as photodetectors or solar cells, or in power devices such as switching devices or rectifiers. Taking the light-emitting diode or the laser diode as an example, its basic structure includes a p-type semiconductor, an n-type semiconductor and an active region between the p-type semiconductor and the n-type semiconductor. By introducing current, carriers combine in the active region and emit light, and wavelength of the light depends on the semiconductor material in the active region. With the development of technology, there is still a lot of demands for research and development of semiconductor optoelectronic devices.

### SUMMARY OF THE DISCLOSURE

The present disclosure provides a semiconductor device. The semiconductor device includes an epitaxial structure, a first electrode, an insulating structure, a stop layer, and a second electrode. The epitaxial structure includes a first semiconductor layer, a second semiconductor layer and an active region located between the first semiconductor layer and the second semiconductor layer. The second semiconductor layer has a first portion and a second portion. The first portion has a first side surface. The first electrode is located under the first semiconductor layer. The insulating structure distributed on the first side surface and having an opening which corresponds to the first electrode. The stop layer contacts the insulating structure distributed on the first side surface. The second electrode is located on the second semiconductor layer. The first portion has a first width, and the second portion has a second width less than the first width.

### BRIEF DESCRIPTION OF THE DRAWINGS

FIG. 1A shows a schematic top view of a semiconductor device in accordance with an embodiment of the present disclosure.

FIG. 1B shows a schematic sectional view of a semiconductor device in accordance with an embodiment of the present disclosure.

FIG. 1C shows a schematic sectional view of a semiconductor device in accordance with an embodiment of the present disclosure.

FIG. 1D shows a schematic sectional view of a semiconductor device in accordance with an embodiment of the present disclosure.

FIG. 1E shows a schematic sectional view of a semiconductor device in accordance with an embodiment of the present disclosure.

FIG. 1F shows a schematic sectional view of a semiconductor device in accordance with an embodiment of the present disclosure.

FIG. 1G shows a schematic sectional view of a semiconductor device in accordance with an embodiment of the present disclosure.

FIG. 1H is a partially enlarged schematic view of a semiconductor device in accordance with an embodiment of the present disclosure.

FIG. 1I shows a schematic sectional view of a semiconductor device in accordance with an embodiment of the present disclosure.

FIG. 1J shows a schematic sectional view of a semiconductor device in accordance with an embodiment of the present disclosure.

FIG. 1K shows a schematic sectional view of a semiconductor device in accordance with an embodiment of the present disclosure.

FIG. 1L shows a schematic sectional view of a semiconductor device in accordance with an embodiment of the present disclosure.

FIG. 1M shows a schematic sectional view of a semiconductor device in accordance with an embodiment of the present disclosure.

FIG. 1N shows a schematic sectional view of a semiconductor device in accordance with an embodiment of the present disclosure.

FIGS. 2A to 2I are schematic views of a method for manufacturing a semiconductor device according to an embodiment of the present disclosure.

FIG. 3A shows a schematic sectional view of a semiconductor component in accordance with an embodiment of the present disclosure.

FIG. 3B shows a schematic sectional view of a semiconductor component in accordance with an embodiment of the present disclosure.

FIG. 4A shows a schematic top view of a display device in accordance with an embodiment of the present disclosure.

FIG. 4B shows a schematic sectional view of a display device in accordance with an embodiment of the present disclosure.

### DETAILED DESCRIPTION OF THE DISCLOSURE

The following embodiments will be described with accompany drawings to disclose the concept of the present disclosure. In the drawings or description, same or similar portions are indicated with same or similar numerals. Furthermore, a shape or a size of a member in the drawings may be enlarged or reduced. Particularly, it should be noted that a member which is not illustrated or described in drawings or description may be in a form that is known by a person skilled in the art.

The semiconductor device of the present disclosure is, for example, a semiconductor optoelectronic device or a non-illumination device. The semiconductor optoelectronic device includes a light-emitting device (such as a light-emitting diode or a laser diode), or a light absorbing device (such as a photo-detector). The qualitative or quantitative analysis of the composition and/or dopant contained in each layer of the semiconductor device of the present disclosure may be conducted by any suitable method, for example, by secondary ion mass spectrometer (SIMS). A thickness of each layer may be obtained by any suitable method, for example, by transmission electron microscopy (TEM) or scanning electron microscope (SEM).

Those with ordinary knowledge in the art should understand that other member(s) may be added on the basis of each embodiment described below. For example, if not otherwise specified, a description similar to “a first layer/structure is on or under a second layer/structure” may include an embodiment in which the first layer/structure is in direct contact with (or physically/directly contacts) the second layer/structure, and may also include an embodiment in which another structure is provided between the first layer/structure and the second layer/structure, such that the first layer/structure and the second layer/structure do not directly contact each other. Furthermore, it should be realized that a positional relationship of a layer/structure may be altered when being observed in different orientations.

In the present disclosure, if not otherwise specified, the general formula InGaP represents Inₓ₀Ga₁₋ₓ₀P, wherein 0<x0<1; the general formula AlInP represents Alₓ₁In₁₋ₓ₁P, wherein 0<x1<1; the general formula InGaN represents Inₓ₂Ga₁₋ₓ₂N, wherein 0<x2<1; the general formula AlGaN represents Alₓ₃Ga₁₋ₓ₃N, wherein 0<x3<1; the general formula AlGaInP represents Alₓ₄Gaₓ₅In₁₋ₓ₄₋ₓ₅P, wherein 0<x4<1, and 0<x5<1; the general formula InGaAsP represents Inₓ₆Ga₁₋ₓ₆Asₓ₇P₁₋ₓ₇, wherein 0<x6<1, and 0<x7<1; the general formula AlGaInAs represents Alₓ₈Gaₓ₉In₁₋ₓ₈₋ₓ₉As, wherein 0<x8<1, and 0<x9<1; the general formula InGaAs represents Inₓ₁₀Ga₁₋ₓ₁₀As, wherein 0<x10<1; and the general formula AlGaAs represents Alₓ₁₁Ga₁₋ₓ₁₁As, wherein 0<x11<1.

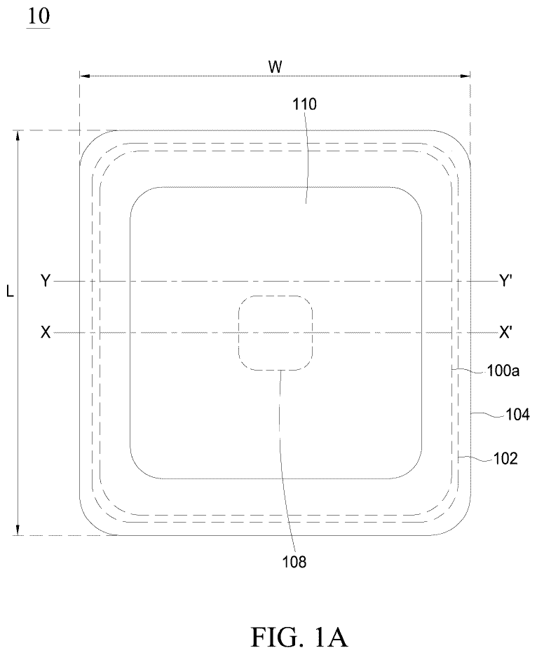

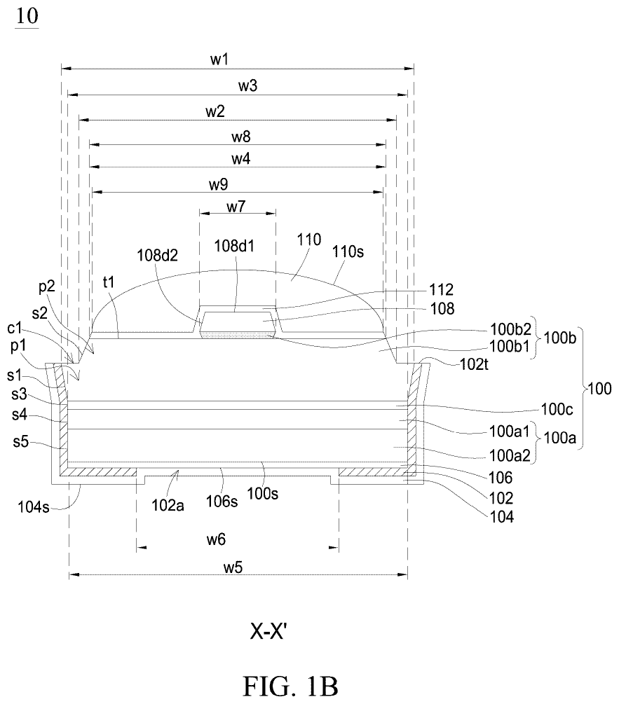

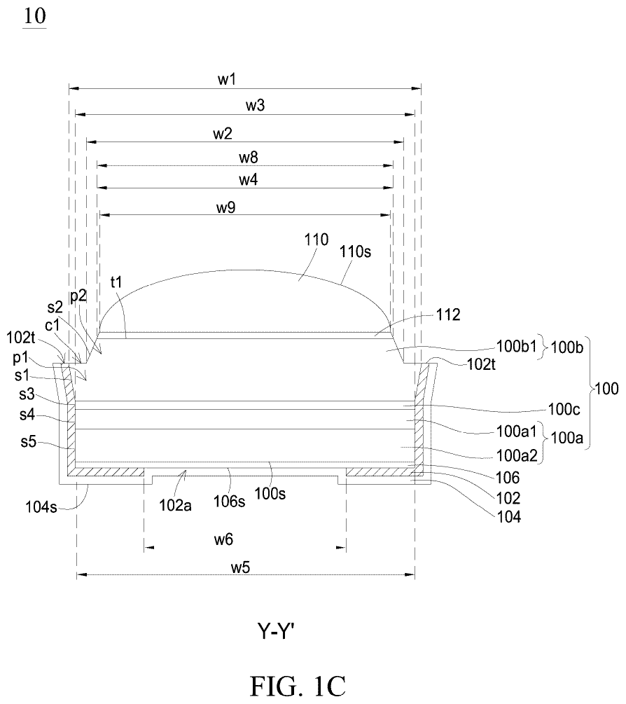

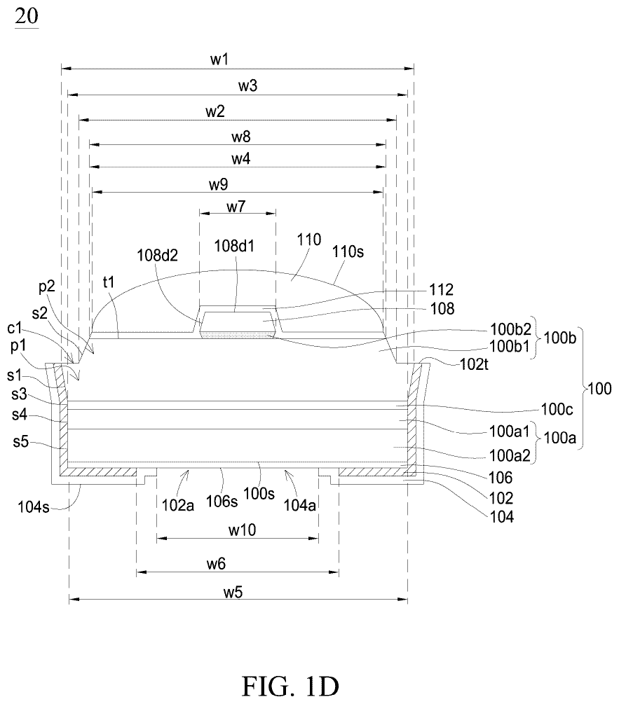

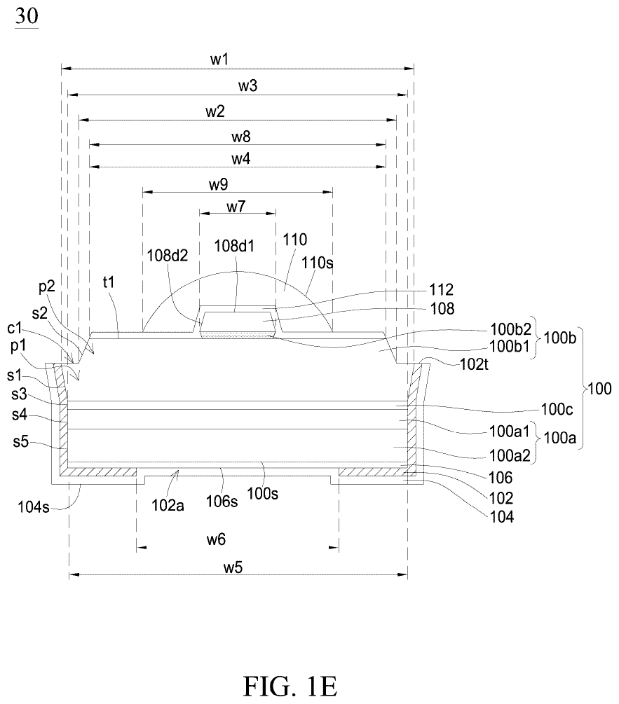

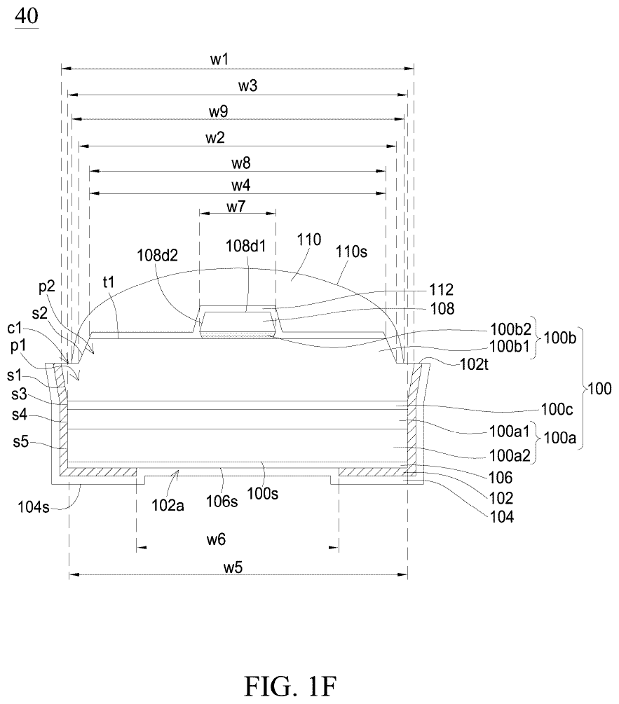

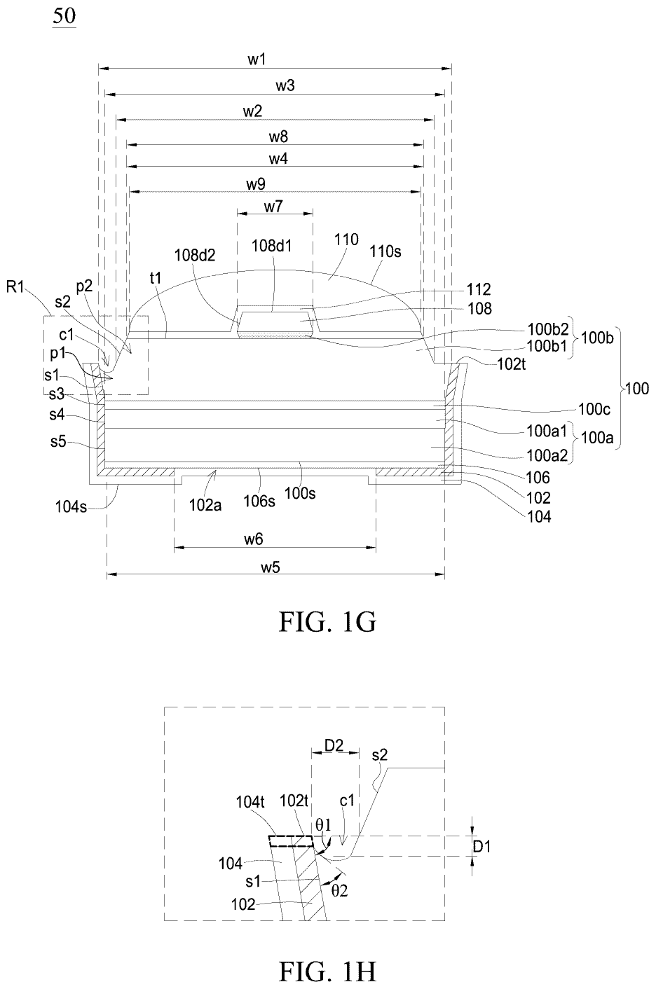

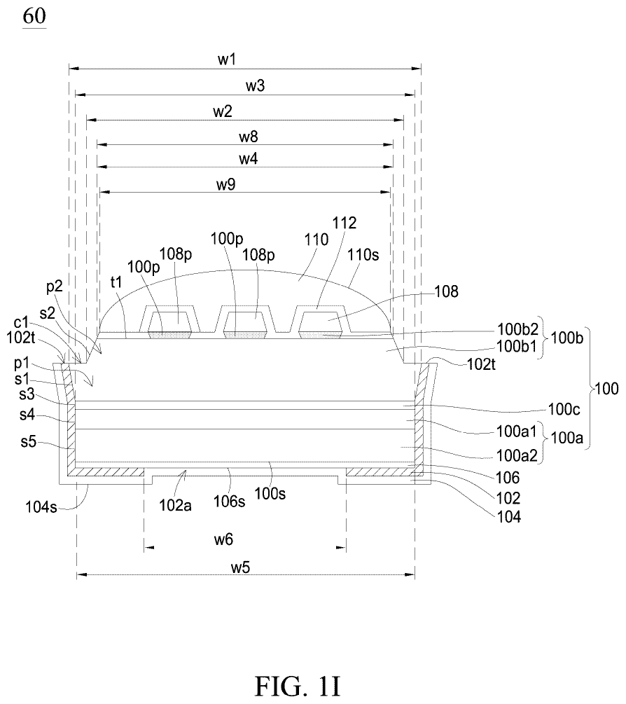

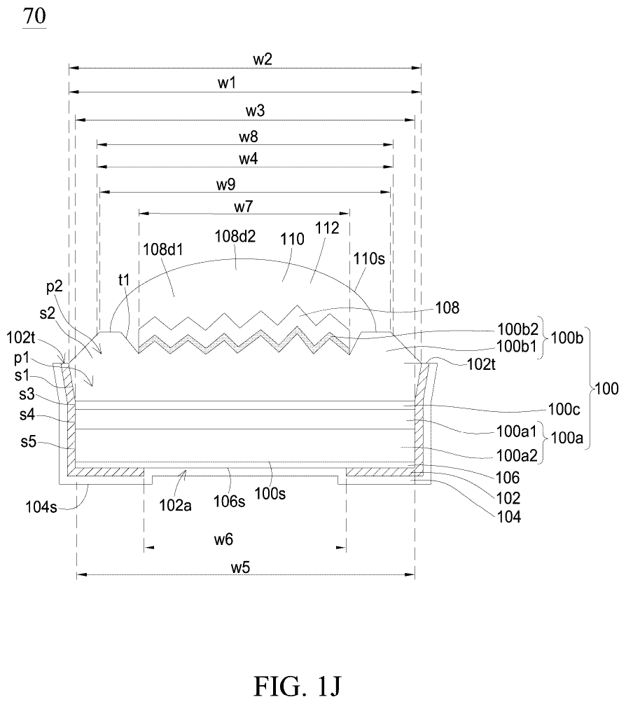

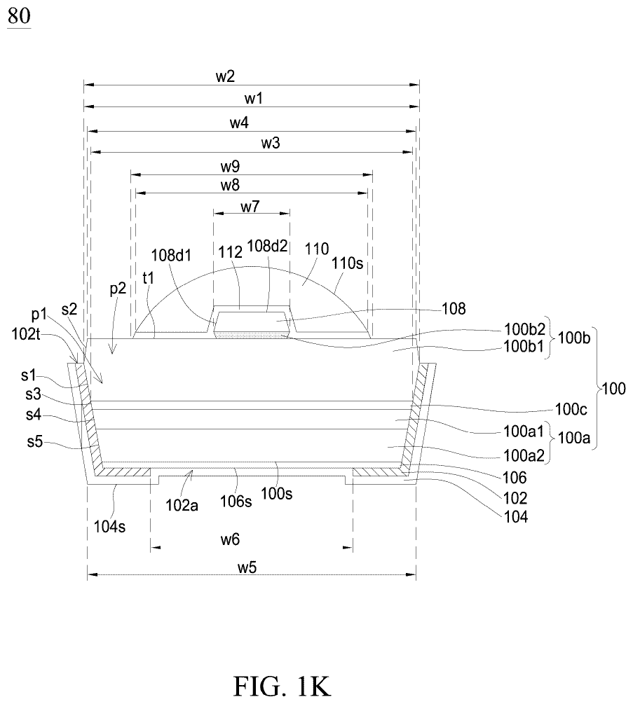

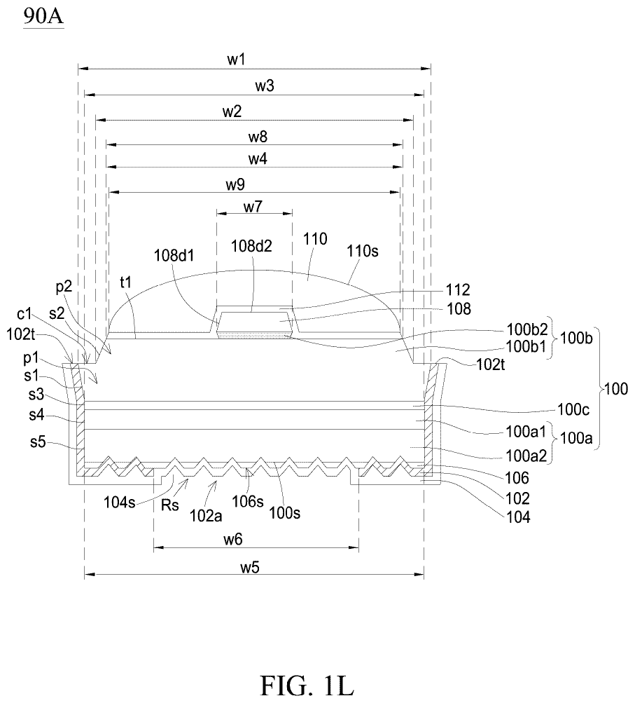

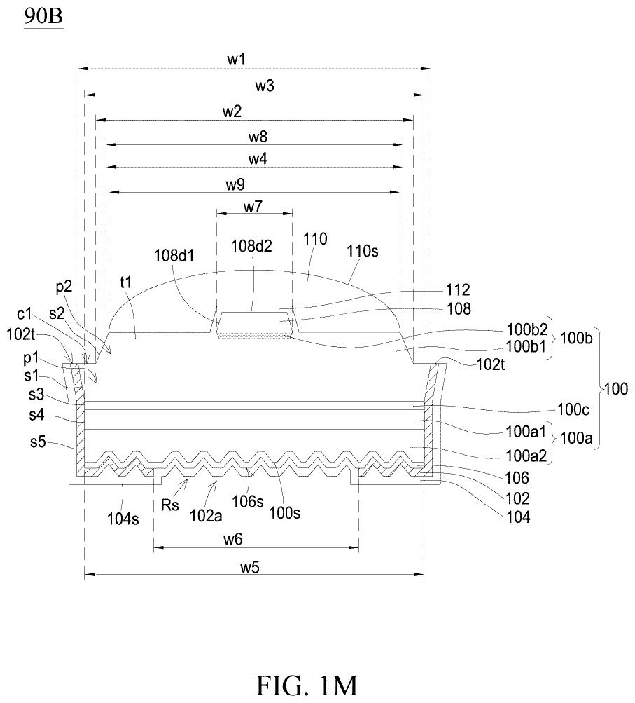

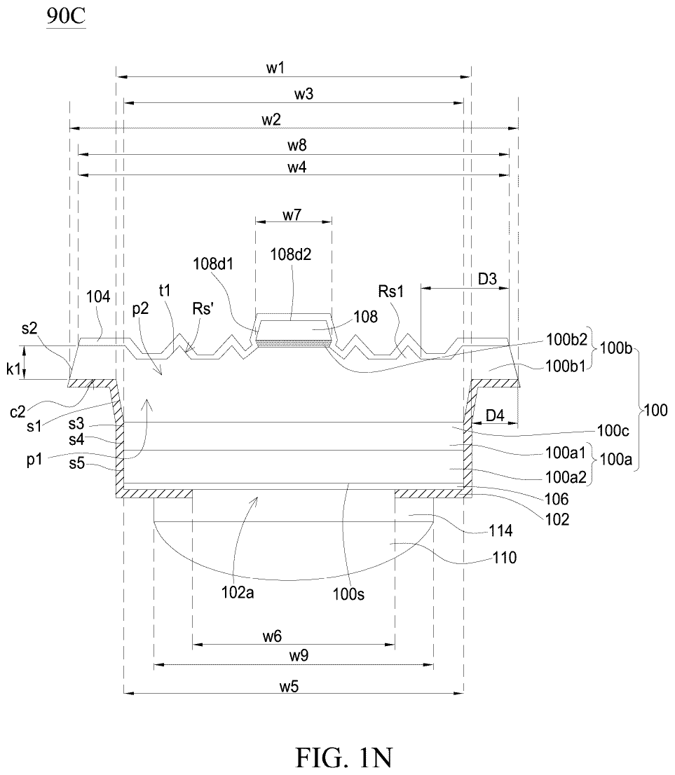

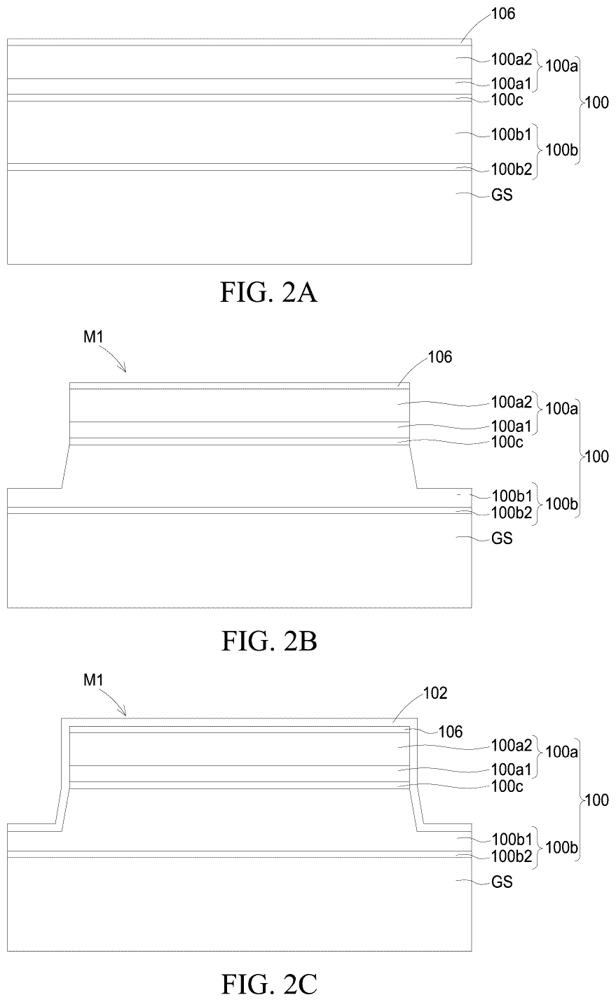

FIG. 1A shows a schematic top view of a semiconductor device 10 in accordance with an embodiment of the present disclosure. FIG. 1B shows a schematic sectional view of the semiconductor device 10 of FIG. 1A along X-X′ line. FIG. 1C shows a schematic sectional view of the semiconductor device 10 of FIG. 1A along Y-Y′ line. As shown in FIG. 1A to FIG. 1C, the semiconductor device 10 includes an epitaxial structure 100, an insulating structure 102 and a stop layer 104. The epitaxial structure 100 includes a first semiconductor structure 100a, a second semiconductor structure 100b and an active region 100c. As shown in FIG. 1B, the second semiconductor structure 100b is located on the first semiconductor structure 100a. The active region 100c is located between the first semiconductor structure 100a and the second semiconductor structure 100b. The first semiconductor structure 100a has a first conductivity type, and the second semiconductor structure 100b has a second conductivity type that is different from the first conductivity type. The first semiconductor structure 100a and the second semiconductor structure 100b can provide electrons and holes (or holes and electrons), respectively. For example, the first conductivity type is n-type and the second conductivity type is p-type, or the first conductivity type is p-type and the second conductivity type is n-type. The conductivity types of the first semiconductor structure 100a and the second semiconductor structure 100b can be adjusted by adding different dopant. For example, the first semiconductor structure 100a includes a first dopant, and the second semiconductor structure 100b includes a second dopant different from the first dopant. Each of the first dopant and the second dopant may be a Group II, Group IV or Group VI element in the periodic table, such as magnesium (Mg), zinc (Zn), carbon (C), silicon (Si) or tellurium (Te).

According to an embodiment, when the semiconductor device 10 is a light-emitting device, the electrons and holes can be combined in the active region 100c to emit a light with a peak wavelength. The light can be visible light or invisible light, and can be incoherent light or coherent light. Specifically, the peak wavelength can be determined by the material composition of the active region 100c. For example, when the material of the active region 100c includes AlGaN, it may emit ultraviolet light with a peak wavelength of 250 nm to 400 nm; when the material of the active region 100c includes InGaN, it may emit deep blue light or blue light with a peak wavelength of 400 nm to 490 nm, green light with a peak wavelength of 490 nm to 550 nm, or yellow or red light with a peak wavelength of 560 nm to 650 nm; when the material of the active region 100c includes InGaP or AlGaInP, it may emit yellow light, orange light or red light with a peak wavelength of 530 nm to 700 nm; when the material of the active region 100c includes InGaAs, InGaAsP, AlGaAs or AlGaInAs, it may emit infrared light with a peak wavelength of 700 nm to 1700 nm.

As shown in FIG. 1A, the semiconductor device 10 may have a length L and a width W. The length L and the width W may be less than or equal to 500 μm, for example, less than or equal to 450 μm, 400 μm, 350 μm, 300 μm, 250 μm, 200 μm, 150 μm, 100 μm, 50 μm, 30 μm or 10 μm, and may be greater than or equal to 1 μm. The semiconductor device 10 may be rectangular or circular when viewed from above. In an embodiment, the length L and the width W of the semiconductor device 10 may be substantially equal and have a square shape. In an embodiment, the semiconductor device 10 has a top surface area (L*W) less than 10000 μm², such as in a range of 1 μm² to 5000 μm² (e.g., 100 μm², 625 μm², 1250 μm², 2000 μm², or 2500 μm²). In an embodiment, a length of a diagonal line of the semiconductor device 10 as viewed from above may be greater than 1 μm and less than 100 μm. According to an embodiment, a total thickness of the epitaxial structure 100 is, for example, in a range of 1 μm to 5 μm, so as to further reduce the thickness of the device, and it is helpful for the miniaturization of the device.

The first semiconductor structure 100a may include the first semiconductor layer 100a1 and the first contact layer 100a2. The first semiconductor layer 100a1 is closer to the active region 100c than the first contact layer 100a2 is. The second semiconductor structure 100b may include the second semiconductor layer 100b1 and the second contact layer 100b2. The second semiconductor layer 100b1 is closer to the active region 100c than the second contact layer 100b2 is. As shown in FIG. 1B, the first semiconductor layer 100a1 and the second semiconductor layer 100b1 may be adjacent to the active region 100c. The second semiconductor layer 100b1 has the first portion p1 and the second portion p2. The second portion p2 is located on the first portion p1 and is connected to the first portion p1. The first portion p1 is closer to the active region 100c than the second portion p2 is. In this embodiment, the first portion p1 has a first width w1, and the second portion p2 has a second width w2. The first width w1 is, for example, the maximum width of the first portion p1. The second width w2 is, for example, the maximum width of the second portion p2. The second width w2 can be smaller than the first width w1. The first portion p1 may also have a third width w3 which is different from the first width w1. The second portion p2 may further have a fourth width w4 different from the second width w2. The third width w3 is, for example, the minimum width of the first portion p1. The fourth width w4 is, for example, the minimum width of the second portion p2. The fourth width w4 may be smaller than the third width w3.

As shown in FIG. 1B, the first portion p1 has a first side surface s1, the second portion p2 has a second side surface s2, and the first portion p1 may optionally have a connecting surface c1 located between the first side surface s1 and the second side surface s2 to connect the first side surface s1 and the second side surface s2. In this embodiment, the active region 100c may have a third side surface s3, the first semiconductor layer 100a1 may have a fourth side surface s4, and the first contact layer 100a2 may have a fifth side surface s5. As shown in FIG. 1B, the first side surface s1, the third side surface s3, the fourth side surface s4 are connected to the fifth side surface s5. The epitaxial structure 100 may have a lower surface 100s. The lower surface 100s may be connected to the fifth side surface s5.

The insulating structure 102 contacts a portion of the surface of the epitaxial structure 100, thereby providing insulation and protecting the epitaxial structure 100. The insulating structure 102 may be a single-layer or multi-layer structure. As shown in FIG. 1B, the insulating structure 102 may be distributed on the first side surface s1, the third side surface s3, the fourth side surface s4, and the fifth side surface s5. The insulating structure 102 may be distributed on a portion or the entire first side surface s1. The insulating structure 102 is optionally distributed on a portion of the lower surface 100s. In this embodiment, the insulating structure 102 may by continuously distributed on a portion of the lower surface 100s, the fifth side surface s5, the fourth side surface s4, the third side surface s3, and the first side surface s1. In an embodiment, a material of the insulating structure 102 may include oxide (such as silicon oxide (SiOx) or aluminum oxide (AlOx)), nitride (such as aluminum nitride (AlN), silicon nitride (SiNx)) or fluoride (such as magnesium fluoride (MgFx). A thickness of the insulating structure 102 is, for example, in a range of 2000 Å˜5000 Å. According to an embodiment, the insulating structure 102 may have multiple layers. For example, the insulating structure 102 may include a first insulating layer (not shown) and a second insulating layer (not shown), the first insulating layer directly contacts the epitaxial structure 100, and the second insulating layer covers the first insulating layer, and a density of the first insulating layer may be higher than the density of the second insulating layer, which helps to further improve the protection effect. For example, the first insulating layer may be formed by atomic layer deposition (ALD), and the second insulating layer may be formed by physical vapor deposition (PVD) or chemical vapor deposition (CVD) (e.g., plasma-enhanced chemical vapor deposition (PECVD)). In an embodiment, the first insulating layer may include aluminum oxide (AlOx), and the second insulating layer may include silicon oxide (SiOx). Optionally, the insulating structure 102 may further include a third insulating layer (not shown) covering the second insulating layer. The density of the third insulating layer may be higher than that of the second insulating layer. For example, the third insulating layer may include aluminum oxide (AlOx) and may be formed by atomic layer deposition (ALD), thereby helping to further improve the protection effect.

The stop layer 104 may contact a portion or the entire insulating structure 102 and may serve as an etching stop layer. The insulating structure 102 may be located between the stop layer 104 and the epitaxial structure 100 and may be in direct contact with the stop layer 104. By arranging the stop layer 104 in the semiconductor device 10, when, for example, a process such as laser irradiation is required to transfer the semiconductor device 10, the stop layer 104 can further protect the insulating structure 102 and the epitaxial structure 100, thereby preventing the insulating structure 102 and the active region 100c of the semiconductor device 10 from being damaged. The stop layer 104 may be a single layer or a multi-layer structure. The material of the insulating structure 102 and the material of the stop layer 104 may be different. For example, according to an embodiment, the stop layer 104 may have better etching resistance than the insulating structure 102 have for fluorine-containing gas (such as carbon tetrafluoride (CF₄)). The stop layer 104 may contact the insulating structure 102 that distributed at different positions. For example, as shown in FIG. 1B, the stop layer 104 may contact the insulating structure 102 distributed on the lower surface 100s, the fifth side surface s5, the fourth side surface s4, the third side surface s3 and/or the first side surface s1. In this embodiment, the stop layer 104 continuously contacts the insulating structure 102.

As shown in FIG. 1B, the insulating structure 102 may have an end upper surface 102t, and the stop layer 104 may have an end upper surface 104t. The end upper surface 102t may be flush with the end upper surface 104t or may not be flush with each other. In some embodiments, a portion of the stop layer 104 may extend to cover the end upper surface 102t, or a portion of the insulating structure 102 may extend to cover the end upper surface 104t. As shown in FIG. 1B, the insulating structure 102 and the stop layer 104 may not cover the second side surface s2 and the connecting surface c1. In some embodiments, the stop layer 104 may not cover the first side surface s1, the second side surface s2, the third side surface s3, the fourth side surface s4 and/or the fifth side surface s5. In an embodiment, the stop layer 104 is located only at the lower surface 100s.

A thickness of the stop layer 104 is, for example, in a range of 1000 Å to 3000 Å. The stop layer 104 may be made of a conductive material or an insulating material. In this embodiment, the material of the stop layer 104 is conductive, and the stop layer 104 can have both protection and conductive functions. According to an embodiment, the conductive material may include a metal oxide. The metal oxide is, for example, indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO) or indium zinc oxide (IZO). In an embodiment, the material of the insulating structure 102 is oxide or nitride (such as aluminum oxide (AlOx), silicon nitride (SiNx) or silicon oxide (SiOx)), and the material of the stop layer 104 is metal oxide (such as indium tin oxide (ITO)). According to an embodiment, when the material of the stop layer 104 is metal oxide, static electricity can be avoided during the device manufacturing process, thereby improving the process stability.

As shown in FIG. 1A and FIG. 1B, the semiconductor device 10 further includes a first electrode 106 and a second electrode 108. The first electrode 106 is located under the first semiconductor structure 100a and can be in direct contact with the first contact layer 100a2 to form an electrical connection. The second electrode 108 is located on the second semiconductor structure 100b and can be in direct contact with the second contact layer 100b2 to form an electrical connection. Each of the first electrode 106 and the second electrode 108 may be a single-layer or multi-layer structure. In this embodiment, the lower surface 100s of the epitaxial structure 100 is also the lower surface of the first contact layer 100a2. The first electrode 106 may contact the entirety or a portion of the lower surface 100s. As shown in FIG. 1B, the first electrode 106 may contact the entire lower surface 100s. The first electrode 106 has a lower surface 106s, and the insulating structure 102 may be distributed on a portion of the lower surface 106s. In an embodiment, the stop layer 104 may also contact a portion of the insulating structure 102 on the lower surface 106s. According to an embodiment, when the semiconductor device 10 is a light-emitting device, the material of the stop layer 104 may be transparent to the light emitted by the active region 100c. The light emitted by the active region 100c may, for example, pass through the first semiconductor structure 100a, the first electrode 106, the insulating structure 102 and the stop layer 104 before emitting. In some embodiments, the lower surface 104s of the stop layer 104 can serve as a main light emitting surface of the semiconductor device 10.

As shown in FIG. 1B, the insulating structure 102 may have an opening 102a corresponding to the first electrode 106, thereby providing a current path required when the semiconductor device 10 operates. As shown in FIG. 1B, the stop layer 104 may fill the opening 102a and directly contact the first electrode 106. In an embodiment, one side of the stop layer 104 is in direct contact with the first electrode 106, and the other side (the lower surface 104s) can be in direct contact with an external conductive structure (not shown) to form an electrical connection. The first electrode 106 may have a fifth width w5. The opening 102a may have a sixth width w6. The second electrode 108 may have a seventh width w7. The sixth width w6 may be less than or equal to the fifth width w5. In this embodiment, the first width w1>the fifth width w5>the second width w2>the sixth width w6>the seventh width w7. The materials of the first electrode 106 and the second electrode 108 may be the same or different. The first electrode 106 and the second electrode 108 include, for example, a transparent conductive material, a metal, or an alloy. The transparent conductive material include a metal oxide, such as indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO) or indium zinc oxide (IZO). Examples of the metal include gold (Au), platinum (Pt), titanium (Ti), aluminum (Al), copper (Cu), and nickel (Ni). The alloy may include two or more of the above metal elements, such as germanium-gold-nickel (GeAuNi), beryllium-gold (BeAu), germanium-gold (GeAu), or zinc-gold (ZnAu). According to an embodiment, the first electrode 106 and the stop layer 104 may include the same material. Thereby, the first electrode 106 and the stop layer 104 can have better adhesion, and the stop layer 104 can be prevented from being easily peeled off. For example, the material of the first electrode 106 and the material of the stop layer 104 both include metal oxides, such as indium tin oxide (ITO).

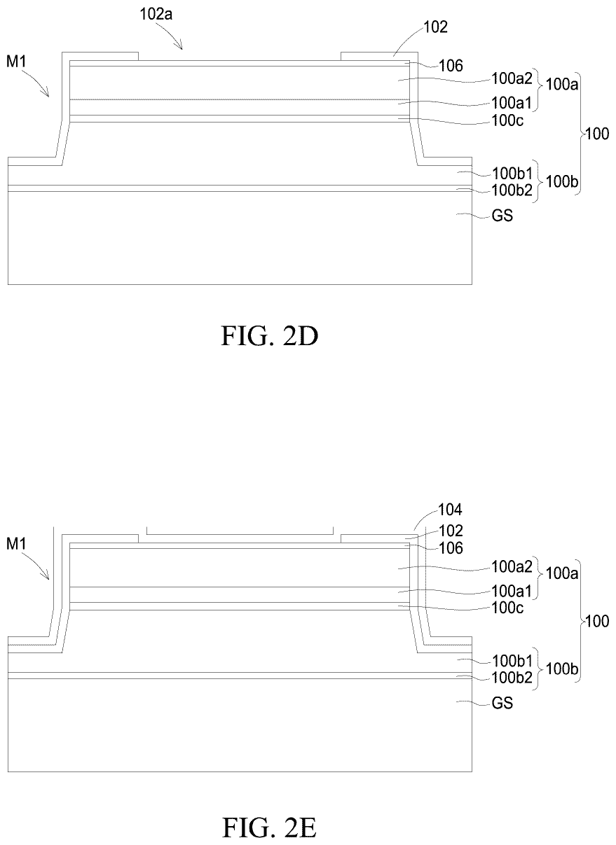

Optionally, the semiconductor device 10 may further include a conductive bump 110 covering the second electrode 108. Specifically, the conductive bump 110 may cover a sidewall 108d1 and an upper surface 108d2 of the second electrode 108. The conductive bump 110 may be used to form an electrical and/or physical connection with an external circuit (such as a circuit board). As shown in FIG. 2B, the upper surface 110s of the conductive bump 110 may not be parallel to the upper surface 108d2 of the second electrode 108. In this embodiment, the upper surface 110s of the conductive bump 110 may be curved. In some embodiments, the conductive bump 110 may also have other cross-sectional shapes such as trapezoidal, rectangular or irregular shapes. The material of the conductive bump 110 may include metal or alloy, and may be, for example, a metal with a low melting point or an alloy with a low liquid melting point. The low melting point or low liquefaction temperature is, for example, lower than 210° C. Specifically, the metal or alloy includes, for example, bismuth (Bi), tin (Sn), indium (In) or an alloy thereof. According to an embodiment, when the semiconductor device 10 needs to be transferred, the upper surface 110s of the conductive bump 110 has a convex arc shape, for example, the semiconductor device 10 can be easily fixed to a bonding substrate (not shown) by burying a side of the conductive bump 110 away from the second electrode 108 into a bonding structure (not shown), and that may be beneficial to a subsequent transfer process of the semiconductor device 10. The conductive bump 110 is located on the second semiconductor layer 100b1 and the second contact layer 100b2.

As shown in FIG. 1B, from a cross-sectional view, an upper surface t1 of the second portion p2 may have an eighth width w8. In this embodiment, the eighth width w8 is the minimum width of the second portion p2, so the eighth width w8 is equal to the fourth width w4. In other embodiments, the eighth width w8 may be greater than or less than the fourth width w4. The conductive bump 110 may have a ninth width w9. The ninth width w9 may be greater than, less than or equal to the eighth width w8. In this embodiment, the eighth width w8 may be equal to the ninth width w9, or the width difference between the eighth width w8 and the ninth width w9 may be less than or equal to 5% of the eighth width w8. According to an embodiment, the top surface area of the conductive bump 110 is, for example, within 10% to 80% of the top surface area of the semiconductor device 10.

Optionally, the semiconductor device 10 may further include an adhesion layer 112 located between the second electrode 108 and the conductive bump 110. The adhesion layer 112 may directly contact the second electrode 108 and the conductive bump 110 to improve the adhesion stability between the second electrode 108 and the conductive bump 110, and to prevent the conductive bump 110 from peeling off from the semiconductor device 10 due to insufficient adhesion strength between the second electrode 108 and the conductive bump 110. According to an embodiment, the adhesion layer 112 and the stop layer 104 may include the same material. Specifically, the adhesion layer 112 may include a conductive material, such as a metal oxide. The metal oxide is, for example, indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO) or indium zinc oxide (IZO).

FIG. 1D shows a schematic sectional view of a semiconductor device 20 in accordance with an embodiment of the present disclosure. In the semiconductor device 20, the material of the stop layer 104 is insulating. Thereby, the stop layer 104 can have both protection and insulation functions. The insulating material may include oxide, nitride or fluoride, such as aluminum oxide (AlOx), silicon nitride (SiNx), silicon oxide (SiOx), titanium oxide (TiOx) or magnesium fluoride (MgFx). As shown in FIG. 1D, the stop layer 104 may have the opening 104a corresponding to the first electrode 106 and the opening 102a of the insulating structure 102. The opening 104a has a width w10. The tenth width w10 may be less than or equal to the sixth width w6. Thereby, the stop layer 104 can fully contact the insulating structure 102 to provide protection. In this embodiment, a portion of the lower surface 106s of the first electrode 106 may directly contact an external conductive structure (not shown) to form an electrical connection. The detailed descriptions of positions, relative relationships and materials of each layer or structure as well as structural variations of the embodiment may be referred to the forward embodiments and are not repeatedly described herein.

FIG. 1E shows a schematic sectional view of a semiconductor device 30 in accordance with an embodiment of the present disclosure. In the semiconductor device 30, the ninth width w9 of the conductive bump 110 is smaller than the eighth width w8. According to an embodiment, the top surface area of the conductive bump 110 is, for example, within 10% to 50% of the top surface area of the semiconductor device 10. In some embodiments, by adjusting the width w9 and the top-view area of the conductive bump 110 to the above ranges, the process margin can be improved to avoid a reduction in yield due to inaccurate alignment when forming the conductive bump 110. The detailed descriptions of positions, relative relationships and materials of each layer or structure as well as structural variations of the embodiment may be referred to the forward embodiments and are not repeatedly described herein.

FIG. 1F shows a schematic sectional view of a semiconductor device 40 in accordance with an embodiment of the present disclosure. In the semiconductor device 40, the ninth width w9 of the conductive bump 110 may be greater than the eighth width w8. In this embodiment, the conductive bump 110 may cover and directly contact the second side surface s2 of the second portion p2. Specifically, the conductive bump 110 may cover a portion or the entire second side surface s2. In other embodiments, the conductive bump 110 may further cover a portion or the entire connecting surface c1. As shown in FIG. 1F, the conductive bump 110 continuously covers the second side surface s2 and the upper surface t1 of the second portion p2. In some embodiments, the contact area between the conductive bump 110 and the epitaxial structure 100 can be further increased by making the conductive bump 110 cover and directly contact the second side surface s2, which helps to further improve the conductive effect. The detailed descriptions of positions, relative relationships and materials of each layer or structure as well as structural variations of the embodiment may be referred to the forward embodiments and are not repeatedly described herein.

FIG. 1G shows a schematic sectional view of a semiconductor device 50 in accordance with an embodiment of the present disclosure. FIG. 1H is a partially enlarged schematic view of a region R1 in the semiconductor device 50. As shown in FIG. 1G and FIG. 1H, in this embodiment, the connecting surface c1 is not flush with the end upper surface 102t and/or the end upper surface 104t. As shown in FIG. 1G and FIG. 1H, the cross-section of connecting surface c1 may be arc-shaped. In some embodiments, the cross-section of the connecting surface c1 may also have other cross-sectional shapes such as an irregular shape. Specifically, the cross-sectional shape of the connecting surface c1 is formed by etching or the like. In this embodiment, the connecting surface c1 may be lower than the end upper surface 102t and/or the end upper surface 104t. In a vertical direction, a maximum distance D1 between the connecting surface c1 and the end upper surface 102t and/or the end upper surface 104t is, for example, in a range of 0.3 μm to 1 μm. Thereby, a portion of the insulating structure 102 near the end upper surface 102t is not connected to the epitaxial structure 100. As shown in FIG. 1H, the end of the insulating structure 102 and the end of the stop layer 104 may form a region R2 that does not directly contact the epitaxial structure 100. In a horizontal direction, a maximum distance D2 between the region R2 and the epitaxial structure 100 is, for example, in a range of 0.5 μm to 2 μm.

In FIG. 1H, the end upper surface 102t is flush with the end upper surface 104t. In another embodiment, the end upper surface 102t may be lower or higher than the end upper surface 104t. As shown in FIG. 1H, the insulating structure 102 may have a first angle θ1 with an imaginary horizontal line passing through the end upper surface 102t, and 30°<θ1<90°. The first side surface s1 and the connecting surface c1 may have a second angle θ2 therebetween. In this embodiment, 0°<θ2<60°. In an embodiment, the insulating structure 102 and/or the stop layer 104 have a width that gradually decreases from the first portion p1 to the second portion p2, that is, the width of the insulating structure 102 close to the end upper surface 102t is smaller than the width away from the end upper surface 102t is and/or the width of the stop layer 104 close to the end upper surface 104t is smaller than the width away from the end upper surface 104t is. The detailed descriptions of positions, relative relationships and materials of each layer or structure as well as structural variations of the embodiment may be referred to the forward embodiments and are not repeatedly described herein.

FIG. 1I shows a schematic sectional view of a semiconductor device 60 in accordance with an embodiment of the present disclosure. In the semiconductor device 60, as shown in FIG. 1I, the second electrode 108 may include a plurality of electrode portions 108p which are separated from each other. The second contact layer 100b2 may also include a plurality of contact portions 100p separated from each other and corresponding to respective portions of the second electrode 108. Each of the numbers of the electrode portions 108p and the contact portions 100p may be between 2 and 10. The plurality of electrode portions 108p may be arranged symmetrically or asymmetrically relative to the geometric center of the second semiconductor structure 100b when viewed from above. According to some embodiments, the electrical performance of the semiconductor device 60 can be further optimized by providing a plurality of electrode portions 108p and a plurality of contact portions 100p. The detailed descriptions of positions, relative relationships and materials of each layer or structure as well as structural variations of the embodiment may be referred to the forward embodiments and are not repeatedly described herein.

FIG. 1J shows a schematic sectional view of a semiconductor device 70 in accordance with an embodiment of the present disclosure. In the semiconductor device 70, as shown in FIG. 1J, the first side surface s1 of the first portion p1 and the second side surface s2 of the second portion p2 can be directly connected (i.e., there is no connecting surface c1). In this embodiment, the first width w1 is equal to the second width w2. The upper surface t1 of the second portion p2 may have a concave-convex structure. The concave-convex structure is, for example, formed by growing the epitaxial structure 100 on a patterned growth substrate (not shown) and leaving a morphology after removing the growth substrate, or by etching the epitaxial structure 100 (e.g., dry etching or wet etching). The second contact layer 100b2 and the second electrode 108 may conformally cover the concave-convex structure of the upper surface t1.

FIG. 1K shows a schematic sectional view of a semiconductor device 80 in accordance with an embodiment of the present disclosure. In the semiconductor device 80, as shown in FIG. 1K, the first side surface s1 of the first portion p1 and the second side surface s2 of the second portion p2 can be directly connected (i.e., there is no connecting surface c1). the first width w1 is equal to second the width w2. The third width w3 is smaller than the fourth width w4. In this embodiment, the third side surface s3, the fourth side surface s4, and the fifth side surface s5 are inclined surfaces, that is, absolute values of the slopes of the third side surface s3, the fourth side surface s4, and the fifth side surface s5 are greater than 0. The third side surface s3, the fourth side surface s4, and the fifth side surface s5 may have the same or different slopes. In some embodiments, the lower surface 100s of the epitaxial structure 100 may also have a roughened structure to further enhance light extraction efficiency. The roughened structure may include, for example, a plurality of protrusions arranged regularly or irregularly, and specific reference may be made to the embodiments of FIG. 1L to FIG. 1N below.

FIG. 1L shows a schematic sectional view of a semiconductor device 90A in accordance with an embodiment of the present disclosure. In the semiconductor device 90A, the lower surface 100s of the epitaxial structure 100 may have a roughened structure Rs. In this embodiment, as shown in FIG. 1L, the first electrode 106 may not continuously contact the lower surface 100s. Specifically, the formation method of this structure is, for example, after forming the first electrode 106 contacting the entire lower surface 100s of the epitaxial structure 100, etching (such as dry etching or wet etching) is performed to remove a portion of the first electrode 106 and the first contact layer 100a2, thereby forming the roughened structure Rs. Furthermore, the insulating structure 102 conformally contacts a portion of the roughened structure Rs, and the stop layer 104 also conformally contacts the insulating structure 102 and the roughened structure Rs.

FIG. 1M shows a schematic sectional view of a semiconductor device 90B in accordance with an embodiment of the present disclosure. In the semiconductor device 90B, the lower surface 100s of the epitaxial structure 100 may have a roughened structure Rs. In this embodiment, as shown in FIG. 1M, the first electrode 106 may continuously contact the lower surface 100s. Specifically, a method for forming this structure is, for example, etching the lower surface 100s of the epitaxial structure 100 (such as dry etching or wet etching) to form the roughened structure Rs, and then forming the first electrode 106 that continuously contacts the lower surface 100s. Similarly, the first electrode 106 conformally contacts the roughened structure Rs, the insulating structure 102 conformally contacts a portion of the first electrode 106, and the stop layer 104 also conformally contacts the insulating structure 102 and the first electrode 106.

The semiconductor device of the embodiment of the present disclosure may also have other different aspects. FIG. 1N shows a schematic sectional view of the semiconductor device 90C in accordance with an embodiment of the present disclosure. In the semiconductor device 90C, the second width w2 is greater than the first width w1, and the fourth width w4 is greater than the third width w3. Optionally, the second portion p2 may further have a connecting surface c2 located between the first side surface s1 and the second side surface s2 to connect the first side surface s1 and the second side surface s2. In this embodiment, the insulating structure 102 is continuously distributed on a portion of the lower surface 100s, the fifth side surface s5, the fourth side surface s4, the third side surface s3, the first side surface s1, and the connecting surface c2. The insulating structure 102 may not cover the second side surface s2.

In this embodiment, the stop layer 104 and the first electrode 106 are located on different sides of the epitaxial structure 100. As shown in FIG. 1N, the stop layer 104 covers the upper surface t1 of the second portion p2 and covers the second electrode 108 and the second contact layer 100b2. Specifically, the stop layer 104 may continuously cover the upper surface t1, the sidewall 108d1 of the second electrode 108, and the upper surface 108d2. Optionally, the semiconductor device 90C may further include the conductive bump 110 contacting the first electrode 106 and a portion of the insulating structure 102. As shown in FIG. 1N, optionally, the semiconductor device 90C may further include a reflective structure 114. The reflective structure 114 is, for example, located between the conductive bump 110 and the first electrode 106, thereby reflecting the light emitted by the active region 100c so that the light is emitted from the upper surface t1 and forms an electrical connection with the first electrode 106. The reflective structure 114 may fill the opening 102a and directly contact the first electrode 106. The reflective structure 114 can be a single-layer or multi-layer structure. Specifically, the material of the reflective structure 114 may include metal. Examples of the metal include chromium (Cr), gold (Au), platinum (Pt), titanium (Ti), aluminum (Al), copper (Cu), or nickel (Ni).

The upper surface t1 of the second portion p2 may optionally have a roughened structure Rs′. For example, before or after forming the second electrode 108, etching (such as dry etching or wet etching) is performed to remove a portion of the second semiconductor layer 100b1, thereby forming the roughened structure Rs′. The stop layer 104 may conformally cover the roughened structure Rs′. In this embodiment, the roughened structure Rs′ has a plurality of protrusions Rs1, and the shortest distance D3 between the protrusions Rs1 and the second side surface s2 in the horizontal direction is greater than a width D4 of the connecting surface c2, thereby enhancing the structural stability of the second portion p2 close to the second side surface s2. In another embodiment, the shortest distance D3 may be less than or equal to the width D4. The shortest distance D3 is, for example, in a range of 0.5 μm to 4 μm. The width D4 is, for example, in a range of greater than 0 μm to less than or equal to 2.5 μm. In an embodiment, the second portion p2 has a thickness k1. The thickness k1 is, for example, in a range from greater than 0.5 μm to less than or equal to 2.5 μm.

In this embodiment, by arranging the stop layer 104 on the upper surface t1, the stop layer 104 can protect the epitaxial structure 100 when, for example, a process such as laser irradiation is required to be applied to the semiconductor device 90C from the upper surface t1 to transfer the semiconductor device 90C. On the other hand, by providing the reflective structure 114, light can be emitted from the upper surface t1, and the light extraction efficiency can be further improved by the roughened structure Rs′. In this embodiment, the material of the stop layer 104 is conductive and can have both protection and conductive functions. In another embodiment, when an insulating material layer is used as the stop layer 104, an opening (not shown) corresponding to the second electrode 108 may be further formed in the stop layer 104, so that the second electrode 108 is in direct contact with an external conductive structure (not shown) to form an electrical connection. The detailed descriptions of positions, relative relationships and materials of each layer or structure as well as structural variations of the embodiments of FIG. 1J to FIG. 1N may be referred to the forward embodiments and are not repeatedly described herein.

Based on the above, in the present disclosure, for example, by arranging the stop layer in the device, a good structural protection effect can be provided for the device, and the production yield can be improved. The above embodiments may be combined or replaced with each other where appropriate, and are not limited to the specific embodiments described. For example, the semiconductor device 20 may also have the conductive bump 110 as in the semiconductor device 30 or the semiconductor device 40, the structure of the region R1 as in the semiconductor device 50, the structure of the second electrode 108 and the second contact layer 100b2 as in the semiconductor device 60, the concave-convex structure as in the semiconductor device 70, the epitaxial structure profile as in the semiconductor device 80, or the roughened structure as in the semiconductor device 90A or the semiconductor device 90B. The semiconductor device 30 or the semiconductor device 40 may also have the structure of the region R1 as in the semiconductor device 50, the structure of the second electrode 108 and the second contact layer 100b2 as in the semiconductor device 60, the concave-convex structure as in the semiconductor device 70, the epitaxial structure profile as in the semiconductor device 80, or the roughened structure as in the semiconductor device 90A or the semiconductor device 90B; the semiconductor device 50 may also have the structure of the second electrode 108 and the second contact layer 100b2 as in the semiconductor device 60, the concave-convex structure as in the semiconductor device 70, the epitaxial structure profile as in the semiconductor device 80, or the roughened structure as in the semiconductor device 90A or the semiconductor device 90B; the semiconductor device 60 may also have the concave-convex structure as in the semiconductor device 70, the epitaxial structure profile as in the semiconductor device 80, or the roughened structure as in the semiconductor device 90A or the semiconductor device 90B; the semiconductor device 70 may also have the epitaxial structure profile as in the semiconductor device 80, or the roughened structure as in the semiconductor device 90A or the semiconductor device 90B; the semiconductor device 80 may also have the roughened structure as in the semiconductor device 90A or the semiconductor device 90B.

FIGS. 2A to 2I are schematic views of a method for manufacturing a semiconductor device 10′ according to an embodiment of the present disclosure. First, a growth substrate GS is provided. As shown in FIG. 2A, the epitaxial structure 100 and the first electrode 106 are formed on the growth substrate GS. The epitaxial structure 100 sequentially includes the second contact layer 100b2, the second semiconductor layer 100b1, the active region 100c, the first semiconductor layer 100a1 and the first contact layer 100a2. The first electrode 106 is formed on the first semiconductor structure 100a to directly contact the first contact layer 100a2. The first electrode 106 is formed by, for example, E-gun evaporation or sputtering. The material of the growth substrate GS is, for example, gallium arsenide (GaAs), indium phosphide (InP), gallium phosphide (GaP), gallium nitride (GaN), sapphire, germanium (Ge) or silicon (Si). After forming the first electrode 106, a heating process may be further performed on the first electrode 106 to form a good electrical contact (such as ohmic contact) between the first electrode 106 and the first contact layer 100a2. The heating process is, for example, a rapid thermal annealing (RTA) process or heating in a furnace.

Then, as shown in FIG. 2B, a first etching process is performed to remove a portion of the epitaxial structure 100 and the first electrode 106. Specifically, a portion of the second semiconductor layer 100b1, a portion of the active region 100c, a portion of the first semiconductor layer 100a1, a portion of the first contact layer 100a2, and a portion of the first electrode 106 may be removed to form a first mesa structure M1.

As shown in FIG. 2C, the insulating structure 102 is formed on the epitaxial structure 100. The insulating structure 102 may be formed by, for example, chemical vapor deposition (CVD), such as plasma enhanced chemical vapor deposition (PECVD) and/or atomic layer deposition (ALD). As shown in FIG. 2C, the insulating structure 102 may be formed to cover and directly contact the second semiconductor layer 100b1, the active region 100c, the first semiconductor layer 100a1, the first contact layer 100a2, and the first electrode 106.

Then, as shown in FIG. 2D, the opening 102a corresponding to the first electrode 106 is formed in the insulating structure 102. The method of forming the opening 102a is, for example, to perform a second etching process on the insulating structure 102. In this embodiment, when a second etching process is performed to form the opening 102a, the first electrode 106 may serve as an etching stop layer.

Then, as shown in FIG. 2E, the stop layer 104 is formed on the insulating structure 102. The stop layer 104 may be formed by, for example, chemical vapor deposition (CVD), such as plasma enhanced chemical vapor deposition (PECVD) and/or atomic layer deposition (ALD). As shown in FIG. 2E, the stop layer 104 may cover and directly contact the insulating structure 102 distributed on the second semiconductor layer 100b1, the active region 100c, the first semiconductor layer 100a1, the first contact layer 100a2 and the first electrode 106. After the stop layer 104 is formed, the stop layer 104 may be optionally subjected to a heating process to improve the light transmittance of the stop layer 104, such as a rapid thermal annealing (RTA) process or heating in a furnace. In an embodiment, the stop layer 104 may be heated at a temperature lower than the temperature used to heat the first electrode 106.

Next, as shown in FIG. 2F, a bonding process is performed to connect the epitaxial structure 100 to the bonding substrate BS via the bonding structure 200. The material of the bonding substrate BS include, for example, sapphire, germanium (Ge) or silicon (Si). According to some embodiments, the material of the bonding structure 200 may include oxide (such as silicon oxide (SiOx) or aluminum oxide (AlOx)), nitride (such as aluminum nitride (AlN), silicon nitride (SiNx)); or polymer (such as benzocyclobutene (BCB), epoxy, polyimide, silicone or SOG (Spin On Glass)). The bonding structure 200 may be a single-layer or multi-layer structure. In this embodiment, the bonding structure 200 may sequentially include a first bonding layer 201, a second bonding layer 202, and a third bonding layer 203. The thickness of the first bonding layer 201 and the third bonding layer 203 may be less than that of the second bonding layer 202. The second bonding layer 202 and the first bonding layer 201 (or the third bonding layer 203) may have different materials, and the second bonding layer 202 and the first bonding layer 201 (or the third bonding layer 203) may have the same material. In an embodiment, the first bonding layer 201 and the third bonding layer 203 include oxide or nitride, and the second bonding layer 202 includes a polymer. In another embodiment, the bonding structure 200 has a single-layer structure and includes a polymer.

Then, the growth substrate GS is removed and the structure is flipped. The method for removing the growth substrate GS is, for example, to perform a third etching process on the growth substrate GS. As shown in FIG. 2G, after the structure is flipped, the second electrode 108 is formed on the second semiconductor structure 100b. In this step, the second contact layer 100b2 may be optionally patterned. For example, as shown in FIG. 2G, a portion of the second contact layer 100b2 that does not overlap with the second electrode 108 in the vertical direction may be removed to form a patterned second contact layer 100b2. In another embodiment, the second contact layer 100b2 may not be patterned, and the portion of the second contact layer 100b2 that does not overlap with the second electrode 108 in the vertical direction may be retained.

Thereafter, as shown in FIG. 2H, a fourth etching process may be performed on the second semiconductor structure 100b, the insulating structure 102, the stop layer 104 and the bonding structure 200. In this step, a portion of the second semiconductor structure 100b, a portion of the insulating structure 102, a portion of the stop layer 104, and a portion of the bonding structure 200 may be removed to form a second mesa structure M2. In detail, the second mesa structure M2 includes the second contact layer 100b2 and a portion of the second semiconductor layer 100b1. In an embodiment, the adhesion layer 112 may be optionally formed on the second semiconductor structure 100b before or after the fourth etching process. The adhesion layer 112 is formed by, for example, E-gun evaporation or sputtering. FIG. 2H shows a structure formed by forming the adhesion layer 112 on the second semiconductor structure 100b and then performing the fourth etching process, but the present disclosure is not limited thereto. By adjusting conditions of the fourth etching process, the first portion p1, the second portion p2, the insulating structure 102 and the stop layer 104 can form an appearance shown in FIG. 2I, and can also form an appearance shown in each of the embodiments (such as embodiments shown in FIGS. 1B-1G and 1I-1M). As shown in FIG. 2H, in this embodiment, the stop layer 104 may have an end upper surface 104t and an end side surface 104w, and a portion of the insulating structure 102 extends to cover the end upper surface 104t but does not cover the end side surface 104w.

Then, as shown in FIG. 2I, the conductive bump 110 may be optionally formed on the second electrode 108. The conductive bump 110 is formed by, for example, E-gun evaporation or sputtering. In this embodiment, the production of a single semiconductor device 10′ is illustrated; however, in practice, a plurality of semiconductor devices 10′ may be simultaneously formed according to the above steps.

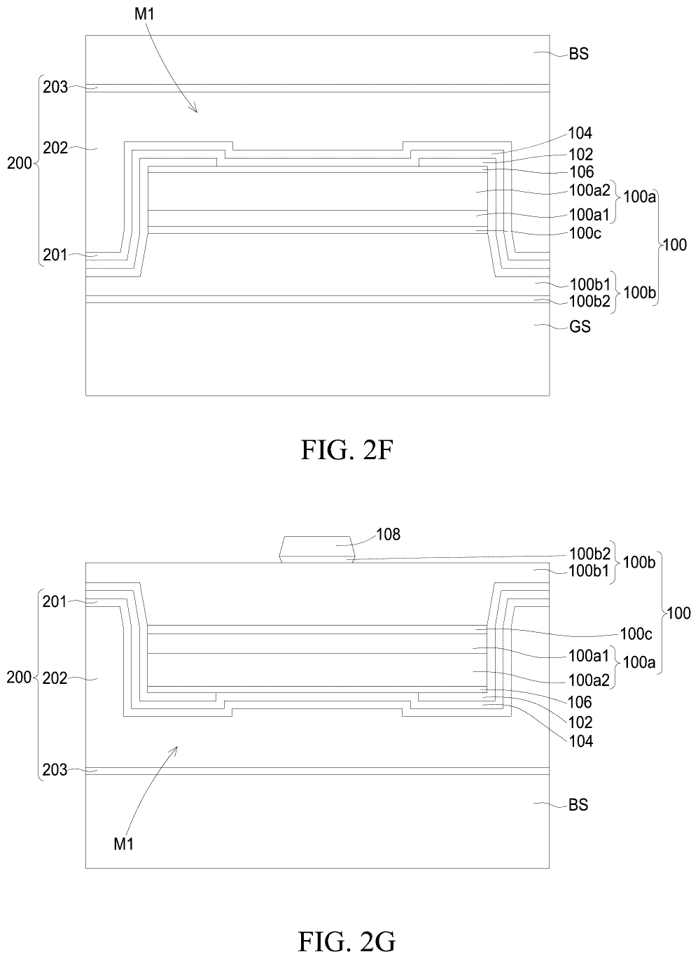

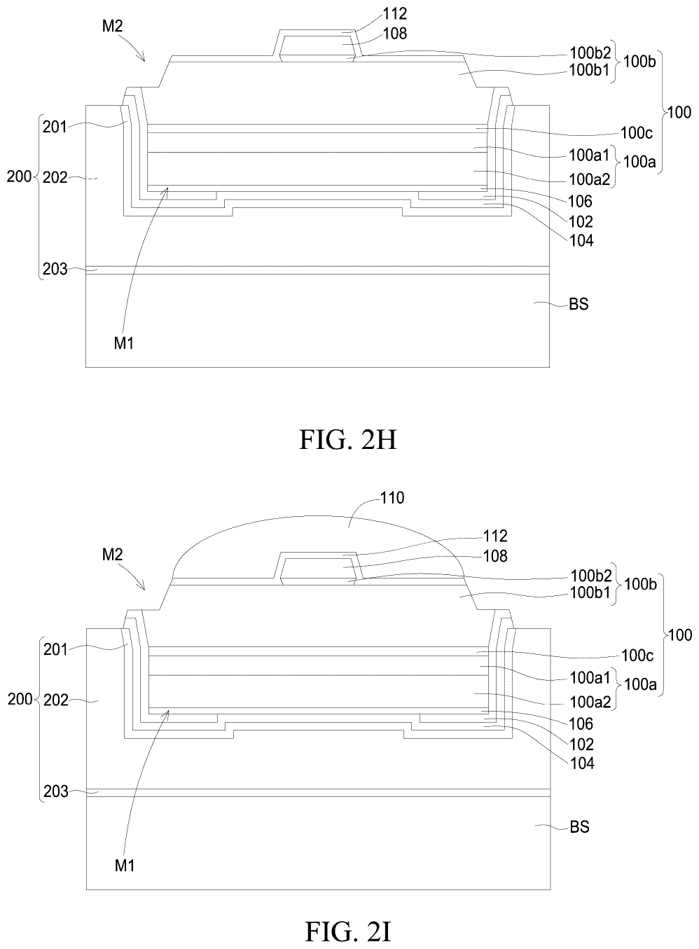

In this embodiment, a semiconductor device 10′ embedded in the bonding structure 200 can be formed through the above steps, which is beneficial for transferring the semiconductor device 10′. After the transfer process is completed, the bonding structure 200 may be further removed. In detail, when transferring the semiconductor device 10′, the insulating structure 102 and the epitaxial structure 100 can be further protected by the stop layer 104 in the semiconductor device 10′, thereby preventing the insulating structure 102 and the active region 100c of the semiconductor device 10′ from being damaged, so as to improve the production yield. Regarding the function of the stop layer 104, the embodiments of FIG. 3A and FIG. 3B and corresponding paragraphs can be referred to for further information.

Specifically, the first/second/third/fourth etching process may include dry etching or wet etching. The dry etching process is, for example, electron cyclotron resonance (ECR), inductively coupled plasma (ICP) or reactive ion etch (RIE). In the present disclosure, for example, by the above method, a good structural protection can be formed for the device, and effects of improving production yield, reducing process steps, and reducing production costs can be obtained.

FIGS. 3A to 3B are schematic views of a method for manufacturing a semiconductor component 300 according to an embodiment of the present disclosure. In this embodiment, a method for manufacturing the semiconductor component 300 including a plurality of the semiconductor devices 10 is taken as an example, but the present disclosure is not limited thereto. The semiconductor component 300 may include a plurality of the semiconductor devices as described in any embodiment of the present disclosure (such as the semiconductor devices 10, 10′, 20, 30, 40, 50, 60, 70, 80, 90A, 90B, or 90C). As shown in FIG. 3A, specifically, for example, referring to steps illustrated in FIG. 2A to FIG. 2G, after performing the fourth etching process as shown in FIG. 2H to form the appearance of FIG. 1B, then performing the step as shown in FIG. 2I to simultaneously form a plurality of the semiconductor devices 10 on the bonding substrate BS, the plurality of the semiconductor devices 10 can be further connected to a temporary carrier TS via an adhesive structure 320, and the bonding structure 200 and the bonding substrate BS can be removed. When removing the bonding structure 200, the stop layer 104 can protect the insulating structure 102 and the epitaxial structure 100, thereby preventing the insulating structure 102 and the active region 100c from being damaged. The material of the temporary carrier TS may include glass, sapphire, or silicon (Si). According to some embodiments, the adhesive structure 320 may include a thermal release tape, a UV release tape, a chemical release tape, a heat-resistant tape, a tape with a dynamic release layer (DRL), or a blue tape. The material of the adhesive structure 320 may include polyimide, benzocyclobutene (BCB), epoxy resin, silicone resin, acrylic resin, polyester or a combination thereof.

As shown in FIG. 3A, a portion of the conductive bump 110 in the semiconductor device 10 may be embedded in the adhesive structure 320. Then, as shown in FIG. 3B, a portion of the adhesive structure 320 (for example, the adhesive structure 320 located between the plurality of the semiconductor devices 10) may be further removed to form the semiconductor component 300 including a plurality of adhesive bodies 320′. In this embodiment, each adhesive body 320′ corresponds to a single semiconductor device 10. However, the present disclosure is not limited thereto, and each adhesive body 320′ may correspond to a plurality of the semiconductor devices 10 as required. Specifically, a portion of the adhesive structure 320 may be removed by dry etching, wet etching, laser lift-off, heating, or UV light irradiation. Similarly, when removing a portion of the adhesive structure 320, the stop layer 104 may also protect the insulating structure 102 and the epitaxial structure 100, thereby preventing the insulating structure 102 and the active region 100c from being damaged, thereby improving the production yield. According to an embodiment, when the material of the stop layer 104 is conductive, after removing the portion of the adhesive structure 320, a portion of the stop layer 104 may be optionally removed, for example, the stop layer 104 covering the first side surface s1, the third side surface s3, the fourth side surface s4, and the fifth side surface s5 may be removed, thereby further avoiding short circuit during subsequent device operation.

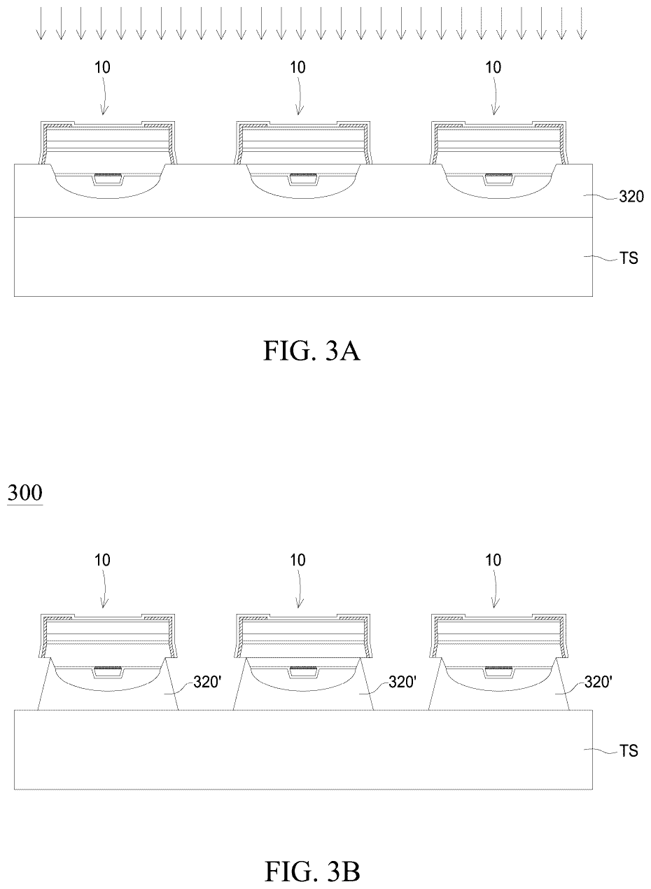

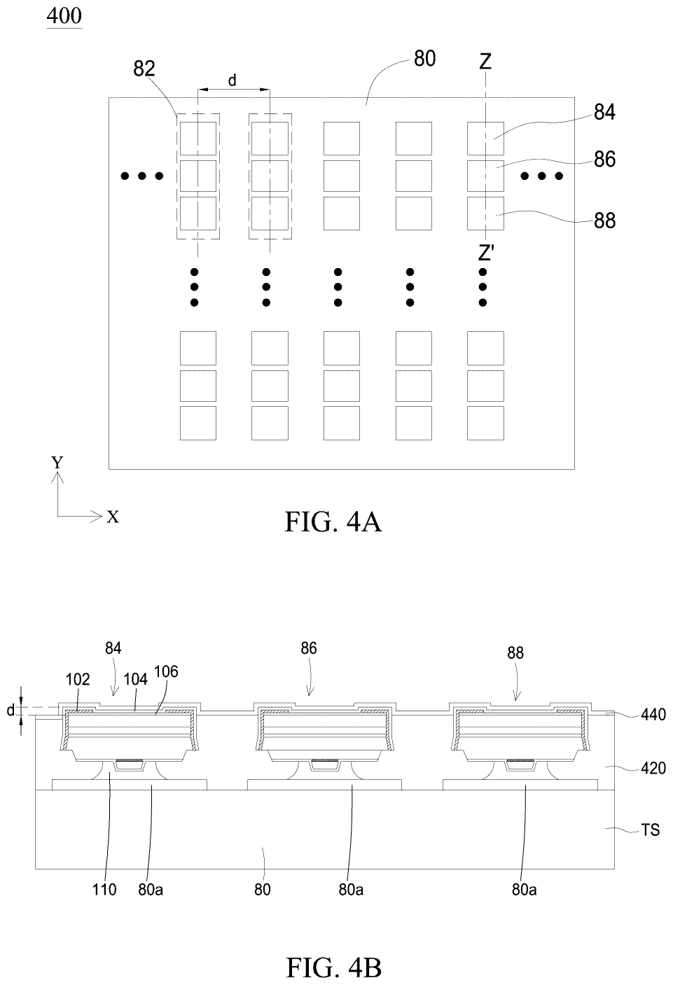

FIG. 4A is a top view of a display device 400 of an embodiment of the present disclosure, and FIG. 4B is a cross-sectional view along the Z-Z′ line in FIG. 4A. As shown in FIG. 4A, the display device 400 may include a target carrier 81 and a plurality of pixel units 82 located on the target carrier 81. The plurality of pixel units 82 are arranged in an array along directions parallel to the x-axis and the y-axis, and are arranged at an interval d1 in the direction parallel to the x-axis. The target carrier 81 can be a single-layer or multi-layer structure. The target carrier 81 may be a printed circuit board (PCB) or a thin-film transistor (TFT) substrate. The material of the target carrier 81 may include glass, polyester, polyimide (PI), bismaleimide triazine (BT) resin, polytetrafluoroethylene (PTFE) resin, phenol (PF) resin or glass fiber epoxy resin (FR4). The number of pixel units 82 can be adjusted according to needs. For example, in an embodiment, the plurality of pixel units 82 included in the display device 400 can provide a resolution of 1920×1080 pixels. In an embodiment, the interval d1 may be less than 1.4 mm. For example, the interval d1 is between 0.2 mm and 1.3 mm, such as 0.75 mm, 0.8 mm, 1 mm, and 1.25 mm. As shown in FIG. 4A, each pixel unit 82 includes a first semiconductor device 84, a second semiconductor device 86 and a third semiconductor device 88 arranged along a direction parallel to the y-axis. Specifically, one or more of the first semiconductor device 84, the second semiconductor device 86, and the third semiconductor device 88 may be the semiconductor device as in the aforementioned embodiment (such as the semiconductor devices 10, 20, 30, 40, or 50). In an embodiment, the first semiconductor device 84, the second semiconductor device 86 and the third semiconductor device 88 are all light-emitting devices and can respectively emit red light, green light and blue light. In an embodiment, the arrangement order of these light-emitting devices can also be adjusted according to needs. For example, the first semiconductor device 84, the second semiconductor device 86, and the third semiconductor device 88 respectively emit red light, blue light, and green light. Each pixel unit 82 can be electrically connected to a circuit (not shown) on a surface of the target carrier 81, so that the light-emitting device(s) therein can receive an external signal and emit light according to the external signal. In an embodiment, the target carrier 81 is bendable and can withstand a curvature radius of less than 50 mm, such as 25 mm or 32 mm.

For the convenience of explanation, FIG. 4B takes the structure of the semiconductor device 10 as an example for illustration. As shown in FIG. 4B, the target carrier 81 may have a conductive structure 80a. The conductive structure 80a may include metal. The first semiconductor device 84, the second semiconductor device 86, and the third semiconductor device 88 may be connected to the conductive structure 80a via the conductive bumps 110, thereby being fixed on the target carrier 81. The display device 400 may further include a dielectric structure 420. The dielectric structure 420 covers the target carrier 81 and covers the side surfaces of the first semiconductor device 84, the second semiconductor device 86 and the third semiconductor device 88. As shown in FIG. 4B, the dielectric structure 420 fills the spaces between the first semiconductor device 84, the second semiconductor device 86, and the third semiconductor device 88. The dielectric structure 420 may include an opaque material or a reflective material. In an embodiment, the material of the dielectric structure 420 may include a matrix and a black material. The matrix may include silicone resin, epoxy resin or a mixture thereof. The black material may include carbon black.

The display device 400 may further include a conductive line 440. As shown in FIG. 4B, the conductive line 440 may cover the dielectric structure 420, the first semiconductor device 84, the second semiconductor device 86 and the third semiconductor device 88 and can be electrically connected to the first semiconductor device 84, the second semiconductor device 86 and the third semiconductor device 88. The conductive line 440 may conformally cover the dielectric structure 420. As shown in FIG. 4B, in this embodiment, the conductive line 440 and the stop layer 104 may be in direct contact to form electrical connection. Or, in another embodiment, for example, when the first semiconductor device 84, the second semiconductor device 86, and the third semiconductor device 88 are the semiconductor devices 20 described in previous embodiment, the conductive line 440 and the first electrode 106 may directly contact each other to form electrical connection. As shown in FIG. 4B, a vertical distance d2 may exist between an upper edge of the dielectric structure 420 and upper edges of the first semiconductor device 84, the second semiconductor device 86, and/or the third semiconductor device 88. The vertical distance d2 is, for example, less than ½ or less than ⅓ of the thickness of the first semiconductor device 84, the second semiconductor device 86 or the third semiconductor device 88, thereby avoiding the conductive line 440 being easily broken due to the vertical distance being too large. The conductive line 440 may be transparent and conductive, for example, may include metal oxide, metal, or alloy. Examples of the metal oxide include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO) or indium zinc oxide (IZO). Examples of the metal include gold (Au), platinum (Pt), titanium (Ti), aluminum (Al), copper (Cu), and nickel (Ni). Examples of the alloy may include two or more metal elements selected from the above metal elements, such as germanium-gold-nickel (GeAuNi), beryllium-gold (BeAu), germanium-gold (GeAu), or zinc-gold (ZnAu). According to an embodiment, the conductive line 440 and the stop layer 104 may include the same material, so that the conductive line 440 and the stop layer 104 can have good adhesion, which helps to improve the structural stability of the display device 400.

In summary, according to the embodiments of the present disclosure, a semiconductor device, a semiconductor component, a display device and a manufacturing method thereof can be provided. For example, by arranging a stop layer in the semiconductor device, a good structural protection can be formed for the devices, the production yield can be improved, the process steps can be reduced, and the production cost can be reduced. Specifically, for example, it is possible to prevent the semiconductor device(s) from being damaged and causing electrical abnormalities during a transfer process, which is beneficial for devices that require miniaturization. The semiconductor device and the semiconductor component of the present disclosure may be applied to products in various fields, such as illumination, display, communication or power supply system, for example, may be used in a light fixture, a monitor, an automotive instrument panel, a television, a computer, a traffic sign, or an outdoor display device.

It should be realized that each of the embodiments mentioned in the present disclosure is used for describing the present disclosure, but not for limiting the scope of the present disclosure. Any obvious modification or alteration is not departing from the spirit and scope of the present disclosure. Furthermore, embodiments may be combined or substituted under proper condition and are not limited to specific embodiments described above. A connection relationship between a specific component and another component specifically described in an embodiment may also be applied in another embodiment and is within the scope as claimed in the present disclosure.

What is claimed is:

1. A semiconductor device, comprising:
an epitaxial structure comprising a first semiconductor layer, a second semiconductor layer having a first portion with a first side surface and a second portion, and an active region located between the first semiconductor layer and the second semiconductor layer;
a first electrode located under the first semiconductor layer;
an insulating structure distributed on the first side surface and having an opening which corresponds to the first electrode;
a stop layer contacting the insulating structure distributed on the first side surface; and
a second electrode located on the second semiconductor layer;
wherein the first portion has a first width, and the second portion has a second width less than the first width.

2. The semiconductor device of claim 1, wherein the stop layer fills the opening and physically contacts with the first electrode.

3. The semiconductor device of claim 1, wherein the first portion is closer to the active region than the second portion is.

4. The semiconductor device of claim 1, wherein the first electrode has a bottom surface, and the insulating structure distributed in a portion of the bottom surface.

5. The semiconductor device of claim 4, wherein the stop layer contacts the insulating structure distributed in the portion of the bottom surface.

6. The semiconductor device of claim 1, wherein the first electrode and the stop layer comprise a same material.

7. The semiconductor device of claim 1, wherein the stop layer comprises a conductive material.

8. The semiconductor device of claim 7, wherein the stop layer comprises metal oxide.

9. The semiconductor device of claim 1, wherein the stop layer comprises an insulating material.

10. The semiconductor device of claim 1, wherein the second electrode has a third width, less than the second width.

11. The semiconductor device of claim 1, further comprising a conductive bump covering the second electrode.

12. The semiconductor device of claim 11, wherein the conductive bump has a first upper surface, the second electrode has a second upper surface which is not parallel to the first upper surface.

13. The semiconductor device of claim 11, further comprising an adhesion layer located between the second electrode and the conductive bump.

14. The semiconductor device of claim 13, wherein the adhesion layer and the stop layer comprise a same material.

15. The semiconductor device of claim 13, wherein the adhesion layer comprises metal oxide.

16. The semiconductor device of claim 1, wherein the stop layer has a thickness in a range of 1000 Å to 3000 Å.

17. The semiconductor device of claim 1, wherein the insulating structure has a first end upper surface, and the stop layer has a second end upper surface which is not flush with the first end upper surface.

18. The semiconductor device of claim 1, wherein the second electrode has a third width, the first electrode has a fourth width greater than the third width.

19. The semiconductor device of claim 1, wherein the first electrode includes a transparent conductive material.

20. A semiconductor component, comprising:
a carrier;
a plurality of semiconductor devices, each comprising:
an epitaxial structure comprising a first semiconductor layer, a second semiconductor layer having a first portion with a first side surface and a second portion, and an active region located between the first semiconductor layer and the second semiconductor layer;
a first electrode located under the first semiconductor layer;
an insulating structure distributed on the first side surface and having an opening which corresponds to the first electrode;
a stop layer covering the insulating structure distributed on the first side surface; and
a second electrode located on the second semiconductor layer; and
an adhesive structure located between the plurality of semiconductor devices and the carrier;
wherein the first portion has a first width, and the second portion has a second width less than the first width.
